(19) United States
(12) Patent Application Publication
(10) Pub. No.: US 2025/0188593 A1
(43) Pub. Date: Jun. 12, 2025

(54) RARE EARTH ROTARY TARGET AND PREPARATION METHOD THEREFOR

(71) Applicants: GRIREM ADVANCED MATERIALS CO., LTD., Beijing (CN); GRIREM HI-TECH CO., LTD., Langfang (CN)

(72) Inventors: Dehong CHEN, Beijing (CN); Zhiqiang WANG, Beijing (CN); Jiamin ZHONG, Beijing (CN); Zongan LI, Beijing (CN); Hongbo YANG, Beijing (CN); Xiaowei ZHANG, Beijing (CN); Daogao WU, Beijing (CN); Siming PANG, Beijing (CN); Yanling ZHANG, Beijing (CN); Jun CHENG, Beijing (CN); Shuang WANG, Beijing (CN); Minglei XU, Beijing (CN); Bingzheng YANG, Beijing (CN); Xiaoqiang ZHANG, Beijing (CN)

(73) Assignees: GRIREM ADVANCED MATERIALS CO., LTD., Beijing (CN); GRIREM HI-TECH CO., LTD., Langfang (CN)

(21) Appl. No.: 19/057,033

(22) Filed: Feb. 19, 2025

Related U.S. Application Data
(63) Continuation of application No. PCT/CN2023/116522, filed on Sep. 1, 2023.

(30) Foreign Application Priority Data
Sep. 7, 2022 (CN) 202211099977.4

(51) Int. Cl. C23C 14/34; H01J 37/34

(52) U.S. Cl. CPC C23C 14/3414; H01J 37/3417; H01J 37/3423; H01J 37/3426; H01J 37/3405; H01J 2237/332

(57) ABSTRACT

Disclosed are a rare earth rotary target and a preparation method therefor. The rare earth rotary target includes a back tube and at least one rare earth target tube welded outside of the back tube; and the back tube and the rare earth target tube are welded via an intermediate welding layer. The intermediate welding layer includes a metal indium solder and an aluminum sheet arranged in the metal indium solder. The aluminum content in the intermediate welding layer is 3-10 wt. %. The back tube, the aluminum sheet, and the rare earth target tube are concentric cylindrical structures. According to the technical solution of the present application, the melting point of the solder is increased, thus achieving the purpose of improving the sputtering power density and a target utilization rate of rare earth rotary targets.

### CROSS-REFERENCE TO RELATED APPLICATIONS

The present application is a continuation of International Application No. PCT/CN2023/116522, filed on Sep. 1, 2023, which claims priority to Chinese Patent Application No. 202211099977.4, filed on Sep. 7, 2022. The disclosures of the above-mentioned applications are hereby incorporated by reference in their entireties.

### TECHNICAL FIELD

The present application relates to the technical field of magnetic materials, storage, and electronic information, and more particularly, to a rare earth rotary target and a preparation method therefor.

### BACKGROUND

The rotary target for magnetron sputtering needs to weld the target tube and the back tube together through a welding layer for use, and the sputtering power density of the target is closely related to the quality of the welding layer. In the prior art, indium is usually used as a solder. On the one hand, since the melting point of indium is only 156.6° C., using a higher power density will lead to the melting of the solder, resulting in the welding-off of the target; on the other hand, the thinning of the target in the later stage of sputtering and the melting of the solder are important factors that restrict the utilization rate of the target. However, the sputtering power density can be increased by using solder with higher melting points, such as Sn, In—Sn alloy, etc. However, the high welding temperature can easily lead to the oxidation of the chemically reactive rare earth target in the welding process, and also increase the welding difficulty of the target.

### SUMMARY

Based on the above-mentioned state of the prior art, it is an objective of the embodiments of the present application to provide a rare earth rotary target and a preparation method therefor, which achieve the purpose of improving sputtering power density and target utilization rate of a rare earth rotary target by adding an aluminum sheet in the welding layers and increasing a solder melting point and combing a thermal treatment process.

In order to achieve the above objective, according to one aspect of the present application, provided is a rare earth rotary target comprising a back tube and at least one rare earth target tube welded outside of the back tube;
wherein; the back tube and the rare earth target tube are welded by means of an intermediate welding layer, wherein the intermediate welding layer comprises a metal indium solder and an aluminum sheet arranged in the metal indium solder; the aluminum content in the intermediate welding layer is 3-10 wt. %; and the back tube, the aluminum sheet, and the rare earth target tube are concentric cylindrical structures.

Further, the rare earth target tube comprises any one of the rotary target tubes of lanthanum, cerium, praseodymium, neodymium, samarium, europium, gadolinium, terbium, dysprosium, holmium, erbium, thulium, ytterbium, lutetium, yttrium, and scandium.

Further, an individual aluminum sheet has a thickness of 0.05-0.15 mm.

According to another aspect of the present application, provided is a preparation method for the rare earth rotary target as described in the first aspect of the present application, comprising the following steps:
filling a metal indium solder between the back tube and the rare earth target tube at a preset welding temperature, and placing an aluminum sheet in the metal indium solder; or placing an aluminum sheet in the metal indium solder in advance, filling the metal indium solder with the placed aluminum sheet between the back tube and the rare earth target tube, and welding the back tube and the rare earth target tube to obtain a welded rare earth rotary target;
subjecting the welded rare earth rotary target to a thermal treatment; and
cooling the thermal-treated rare earth rotary target to room temperature and cleaning the same.

The method further includes:
pre-coating the aluminum sheet with a layer of metal indium solder prior to filling.

Further, the preset welding temperature is 190-230° C.

Further, the thermal treatment includes the following steps:
cooling the welded rare earth rotary target to room temperature and then cleaning the same;
placing the cleaned rare earth rotary target in a vacuum thermal treatment furnace, and vacuum pumping to less than 10−3 Pa; and
subjecting the rare earth rotary target to a direct thermal treatment or a thermal treatment after charging an inert gas, wherein the thermal treatment temperature is 140° C.-640° C., and the thermal treatment time is 0.5-50 h.

Further, the thermal treatment is a step-wised insulation treatment including:
a thermal treatment at 140° C. for 0.5-1 h;
a thermal treatment at 157° C. for 1-3 h;
a thermal treatment at 200° C. for 1-3 h;
a thermal treatment at 250° C. for 1-3 h;
a thermal treatment at 300° C. for 1-3 h;
a thermal treatment at 350° C. for 1-5 h;
a thermal treatment at 400° C. for 1-5 h;
a thermal treatment at 450° C. for 1-5 h;
a thermal treatment at 500° C. for 1-5 h;
a thermal treatment at 550° C. for 1-5 h;
a thermal treatment at 600° C. for 1-5 h; and
a thermal treatment at 630° C. for 1-6 h.

In summary, the embodiments of the present application provide a rare earth rotary target and a preparation method therefor. The rare earth rotary target comprises a back tube and at least one rare earth target tube welded outside of the back tube; the back tube and the rare earth target tube are welded by means of an intermediate welding layer, wherein the intermediate welding layer comprises a metal indium solder and at least one aluminum sheet arranged in the metal indium solder, the aluminum content in the intermediate welding layer is 3-10 wt. %. An individual aluminum sheet has a thickness of 0.05-0.15 mm. The back tube, the aluminum sheet, and the rare earth target tube are concentric cylindrical structures. According to the technical solution of the embodiments of the present application, starting from the aspects of target welding, solder alloying, etc. by adding an aluminum sheet in the welding layers and combining the thermal treatment process, selecting a reasonable thickness can better control the melting point of the solder, reduce the solder composition segregation, and reduce the contamination of the target by the solder. The thermal treatment is carried out using a step-wised insulation treatment to prevent the solder from melting and flowing out while ensuring the uniformity of the solder. By step-wise increasing the temperature, the solder indium and aluminum gradually form a high melting point alloy, which increases the melting point of the alloy solder and achieves the purpose of improving the sputtering power density and utilization rate of rare earth rotary target, achieving low-temperature welding and slowing down the oxidation of rare earth target.

### BRIEF DESCRIPTION OF THE DRAWINGS

FIG. 1 is a schematic diagram of the overall structure of a rare earth rotary target provided in an embodiment of the present application.

FIG. 2 is a cross-sectional view at c of the rare earth rotary target shown in FIG. 1.

FIG. 3 is a flowchart of the preparation method for a rare earth rotary target provided in an embodiment of the present application.

### DETAILED DESCRIPTION OF THE EMBODIMENTS

In order to make the objective, technical solution, and advantages of the present application clearer, the following is a detailed explanation of the present application, combined with specific examples and referring to the accompanying drawings. It is to be understood that this description is made only by way of example and not as a limitation on the scope of the present application. Further, in the following description, descriptions of publicly known structures and techniques are omitted to avoid unnecessarily confusing the concepts of the present application.

It should be noted that unless otherwise defined, technical or scientific terms used in one or more embodiments of the present application shall have the ordinary meaning as understood by one of ordinary skill in the art to which the present disclosure belongs. The use of “first”, “second”, and similar terms in one or more embodiments of the present disclosure does not denote any order, quantity, or importance, but rather is used to distinguish one element from another. The word “comprising” or “comprises”, and the like, means that the elements or items preceding the word encompass the elements or items listed after the word and equivalents thereof, but do not exclude other elements or items. Terms such as “connected” or “attached” are not limited to physical or mechanical connections, but may include electrical connections, whether direct or indirect. Terms such as “up”, “down”, “left”, “right”, etc. are only used to indicate a relative positional relationship. When the absolute position of the described objective changes, the relative positional relationship may also change accordingly.

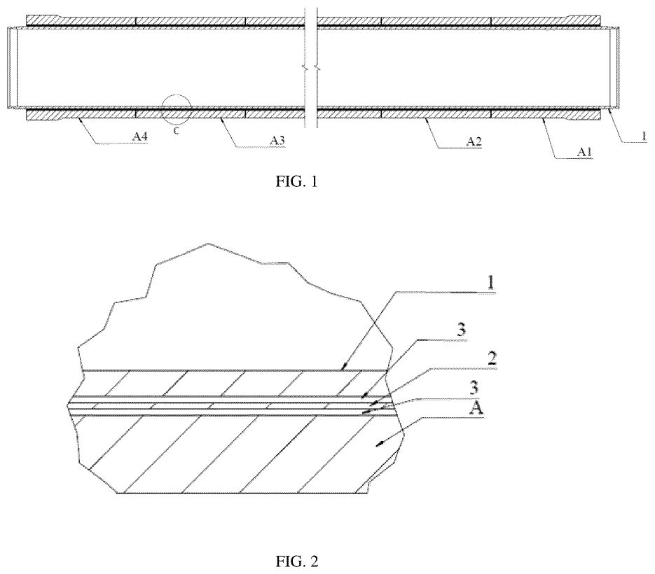

Below, the technical solution of the present application will be described in detail with reference to the accompanying drawings. According to an embodiment of the present application, provided is a rare earth rotary target. An overall structural diagram of the rare earth rotary target is shown in FIG. 1. The rare earth rotary target comprises a back tube 1 and at least one rare earth target tube welded outside of the back tube. Four rare earth target tubes are illustrated in FIG. 1, including rare earth target tube A1, rare earth target tube A2, rare earth target tube A3, and rare earth target tube A4. The above-mentioned rare earth target tubes are assembled with each other, and a certain gap is left at the assemble position according to the expansion coefficient.

FIG. 2 shows a cross-sectional view at c of the rare earth rotary target as shown in FIG. 1. As shown in FIG. 2, the back tube 1 and the rare earth target tube A are welded by means of an intermediate welding layer. The intermediate welding layer comprises a metal indium solder 3 and an aluminum sheet 2 arranged in the metal indium solder. The aluminum content in the intermediate welding layer is 3-10 wt. %. The back tube 1, the aluminum sheet 2, and the rare earth target tube A are concentric cylindrical structures. The rare earth target tube A comprises a rotary target tube of any one of lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), and yttrium (Y). An individual aluminum sheet 2 has a thickness of 0.05-0.15 mm. The selection of the thickness can enable better control of the melting point of the solder and make the composition more uniform. If the thickness is too large, the alloying time is long, and the composition deviation is large. A too small thickness can easily lead to a higher composition of the target in the solder layer, while also contaminating the target.

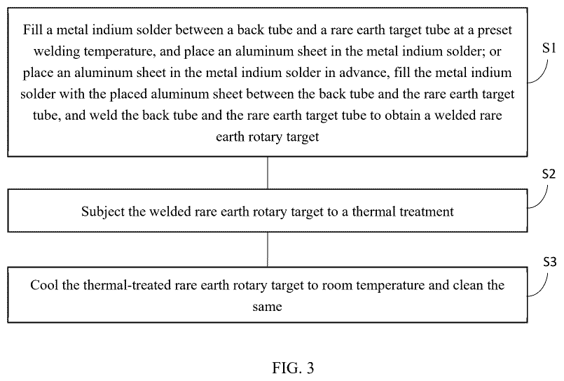

According to an embodiment of the present application, also provided is a preparation method of a rare earth rotary target that is a rare earth rotary target according to the above-mentioned embodiment of the present application. A flow chart of a preparation method for the rare earth rotary target is shown in FIG. 3, the method comprising the following steps.

S1, filling a metal indium solder between the back tube and the rare earth target tube at a preset welding temperature, e.g., 190-230° C., and placing an aluminum sheet in the metal indium solder; or placing an aluminum sheet in the metal indium solder in advance, filling the metal indium solder with the placed aluminum sheet between the back tube and the rare earth target tube, and welding the back tube and the rare earth target tube to obtain a welded rare earth rotary target. To improve the quality of the weld, the aluminum sheet may be pre-coated with a layer of metallic indium solder prior to filling.

S2, subjecting the welded rare earth rotary target to a thermal treatment, the thermal treatment comprising the steps of.
cooling the welded rare earth rotary target to room temperature and then cleaning the same;
placing the cleaned rare earth rotary target in a vacuum thermal treatment furnace, and vacuum pumping to less than 10−3 Pa; and
subjecting the rare earth rotary target to a direct thermal treatment or a thermal treatment after charging an inert gas, wherein the thermal treatment temperature is 140° C.-640° C., and the thermal treatment time is 0.5-50 h. Preferably, the thermal treatment is a step-wised insulation treatment including the following treatments:
a thermal treatment at 140° C. for 0.5-1 h;
a thermal treatment at 157° C. for 1-3 h;
a thermal treatment at 200° C. for 1-3 h;
a thermal treatment at 250° C. for 1-3 h;
a thermal treatment at 300° C. for 1-3 h;
a thermal treatment at 350° C. for 1-5 h;
a thermal treatment at 400° C. for 1-5 h;
a thermal treatment at 450° C. for 1-5 h;
a thermal treatment at 500° C. for 1-5 h;
a thermal treatment at 550° C. for 1-5 h;
a thermal treatment at 600° C. for 1-5 h; and
a thermal treatment at 630° C. for 1-6 h.

The thermal treatment process according to this embodiment of the present application is preferably carried out in a step-wised insulation process in such a manner that the solder does not melt and flow out while ensuring the uniformity of the solder. By step-wise increasing the temperature, the solder indium and aluminum gradually form a high melting point alloy.

S3, cooling the thermal-treated rare earth rotary target to room temperature and cleaning the same.

The rare earth rotary target prepared by the above method has a welding rate of over 95% and a melting point of over 400° C. for the solder material; the sputtering power density of the target is increased by more than 30% compared to pure indium welding, with a power density of 2-12 W/cm², preferably 6-10 W/cm²; The utilization rate of the target is over 88%.

Specific examples and experimental data are given below.

### Example 1

The rotary target had a total length of 1600 mm and was formed by assembling 9 terbium target tubes. The target tubes at the two ends were dog-bone-shaped, with outer diameters of 165 mm and 158 mm respectively. The outer diameter of the middle region was 158 mm. The clearance between the target tube and the back tube was 1 mm. The aluminum sheet was columnar and concentric with the target tube and was composed of two 0.125 mm thick aluminum rings. The aluminum content in the welding layer was 10%. The welding was completed at 220° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h. The total thermal treatment time was 35 h, and the melting point of the solder reached 600° C. The welding rate was >95%. The sputtering target power was 5 W/cm²; the target utilization rate was 90%; the deviation of aluminum content was ±0.1%, and the Tb content in the weld layer was <10 ppm.

### Example 2

The sputtering target power was 8 W/cm², and the rest of the conditions were the same as in Example 1.

### Example 3

The sputtering target power was 10 W/cm², and the rest of the conditions were the same as in Example 1.

### Example 4

There were one 0.05 mm and two 0.1 mm aluminum sheets, and the rest of the conditions were the same as in Example 1.

### Example 5

The sputtering target power was 12 W/cm², and the rest of the conditions were the same as in Example 1.

### Example 6

The material of the target was dysprosium, and the rest were the same as those in Example 6.

### Example 7

The material of the target was gadolinium and there were two 0.125 mm aluminum sheets with an aluminum content of 10%. The rest of the conditions were the same as in Example 1.

### Example 8

The material of the target was yttrium and there were one 0.05 mm and two 0.1 mm aluminum sheets. The rest conditions were the same as those in Example 1.

### Example 9

The rotary target had a total length of 1500 mm and was formed by assembling 6 scandium target tubes. The target tubes at the two ends were dog-bone-shaped, with outer diameters of 112 mm and 108 mm respectively. The outer diameter of the middle region was 108 mm. The clearance between the target tube and the back tube was 1 mm. The aluminum sheet was columnar and concentric with the target tube and was composed of one 0.05 mm and one 0.08 mm thick aluminum ring. The aluminum content in the welding layer was 5%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Example 10

The rotary target had a total length of 1500 mm and was formed by assembling 6 ytterbium target tubes. The target tubes at the two ends were dog-bone-shaped, with outer diameters of 112 mm and 108 mm respectively. The outer diameter of the middle region was 108 mm. The clearance between the target tube and the back tube is 1 mm. The aluminum sheet was columnar and concentric with the target tube and was composed of one 0.06 mm and one 0.1 mm thick aluminum ring. The aluminum content in the welding layer was 6%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Example 11

The rotary target had a total length of 1500 mm and was formed by assembling 6 lanthanum target tubes. The target tubes at the two ends were dog-bone-shaped, with outer diameters of 112 mm and 108 mm respectively. The outer diameter of the middle region was 108 mm. The clearance between the target tube and the back tube was 1 mm. The aluminum sheet was columnar and concentric with the target tube and was composed of one 0.05 mm aluminum ring, one 0.06 mm, and one 0.1 mm thick aluminum ring. The aluminum content in the welding layer was 8%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Example 12

The rotary target had a total length of 1500 mm and was formed by assembling 6 holmium target tubes. The target tubes at the two ends were dog-bone-shaped, with outer diameters of 112 mm and 108 mm respectively. The outer diameter of the middle region was 108 mm. The clearance between the target tube and the back tube was 1 mm. The aluminum sheet was columnar and concentric with the target tube and was composed of one 0.05 mm aluminum ring and two 0.1 mm aluminum rings. The aluminum content in the welding layer was 10%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Example 13

The rotary target had a total length of 1500 mm and was formed by assembling 7 lanthanum target tubes. The target tubes at the two ends were dog-bone-shaped, with outer diameters of 112 mm and 108 mm respectively. The outer diameter of the middle region was 108 mm. The clearance between the target tube and the back tube was 1 mm. The aluminum sheet was columnar and concentric with the target tube and was composed of one 0.07 mm, one 0.08 mm, and one 0.1 mm thick aluminum ring. The aluminum content in the welding layer was 10%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Example 14

The rotary target had a total length of 1500 mm and was formed by assembling 8 samarium target tubes. The target tubes at the two ends were dog-bone-shaped, with outer diameters of 112 mm and 108 mm respectively. The outer diameter of the middle region was 108 mm. The clearance between the target tube and the back tube was 1 mm. The aluminum sheet was columnar and concentric with the target tube and was composed of one 0.1 mm and one 0.15 mm thick aluminum rings. The aluminum content in the welding layer was 10%. The welding was completed at 210° C. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; 9) 500° C.-3 h; 10) 550° C.-4 h; 11) 600° C.-4 h; and 12) 630° C.-4 h.

### Comparative Example 1

The rotary target had a total length of 1600 mm and was formed by assembling 9 terbium target tubes. The outer diameters of A4 and A1 at the dog head were 165 mm and 158 mm respectively. The outer diameter of the middle region was 158 mm. The clearance between the target tube and the back tube was 1 mm. No aluminum sheet was present and the content of aluminum in the welding layer was 0%. The welding was completed at 220° C., with a welding rate of >95%. The sputtering target power was 5 W/cm² and the target utilization was 82%.

### Comparative Example 2

The sputtering target power was 6 W/cm². The rest of the conditions were the same as in Comparative Example 1 and the target was welded off in the coating process.

### Comparative Example 3

There were two 0.02 mm, two 0.03 mm, and one 0.15 mm aluminum thick aluminum sheets, and the rest of the conditions were the same as in Example 1.

### Comparative Example 4

There was one 0.25 mm aluminum sheet and the rest of the conditions were the same as in Example 1.

### Comparative Example 5

The structure of the target was the same as that in Example 1, and the thermal treatment process was different. The thermal treatment process was as follows: 1) 140° C.-0.5 h; 2) 157° C.-3 h; 3) 200° C.-4 h; 4) 300° C.-5 h; 5) 400° C.-10 h; 6) 500° C.-10 h; and 7) 630° C.-17.5 h. The total thermal treatment time was 50 h.

### Comparative Example 6

The thermal treatment process was 630° C.-17.5 h, and the rest of the conditions were the same as in Example 1.

### Comparative Example 7

The structure of the target was the same as that of Example 1, and there was one 0.13 mm aluminum sheet. The aluminum content in the weld layer was 5%. The thermal treatment process included: 1) 140° C.-0.5 h; 2) 157° C.-1.5 h; 3) 200° C.-1.5 h; 4) 250° C.-1.5 h; 5) 300° C.-2 h; 6) 350° C.-3 h; 7) 400° C.-3 h; 8) 450° C.-3 h; and 9) 480° C.-3 h.

### Comparative Example 8

There was one 0.05 mm aluminum sheet with an aluminum content of 2%. The thermal treatment time included: 1) 140° C.-0.5 h; 2) 157° C.-3 h; 3) 200° C.-4 h; 4) 300° C.-5 h; and 5) 330° C.-10 h. The rest of the conditions were the same as in Example 1.

### Comparative Example 9

There was one 0.07 mm, one 0.1 mm, and two 0.15 mm aluminum sheets with an aluminum content of 15%, and the rest of the conditions were the same as in Example 1.

### Comparative Example 10

The rotary target had a total length of 1600 mm and was formed by assembling 9 terbium target tubes. The target tubes at the two ends were dog-bone-shaped, with outer diameters of 165 mm and 158 mm, respectively. The outer diameter of the middle region was 158 mm. The clearance between the target tube and the back tube was 1 mm. The aluminum sheet was columnar and concentric with the target tube. The welding was carried out with a solder with an aluminum content of 10%. The welding was completed at 650° C. The sputtering target power was 5 W/cm².

Tables 1 and 2 show the comparison of performance parameters between the above examples and the comparative examples.

TABLE 1
Table (1) of performance parameters of each example and comparative example

| | | | | Clearance | | | |
|---|---|---|---|---|---|---|---|
| | Material | Outer | Length | between | | Aluminum | |
| | of | diameter | of | target tube | Aluminum | content in | Thermal |
| | target | of | target/ | and back | sheet | welding | treatment |
| No. | tube | target | mm | tube/mm | thickness/mm | layer | system |
| Ex. 1 | Tb | 158 | 134 | 1 | 0.125 + 0.125 | 10% | 1) 140° C.-0.5 h; |
| | | | | | | | 2) 157° C.-1.5 h; |
| | | | | | | | 3) 200° C.-1.5 h |
| | | | | | | | 4) 250° C.-1.5 h; |
| | | | | | | | 5) 300° C.-2 h; |
| | | | | | | | 6) 350° C.-3 h; |
| | | | | | | | 7) 400° C.-3 h; |
| | | | | | | | 8) 450° C.-3 h; |
| | | | | | | | 9) 500° C.-3 h; |
| | | | | | | | 10) 550° C.-4 h; |
| | | | | | | | 11) 600° C.-4 h; |
| | | | | | | | and |
| | | | | | | | 12) 630° C.-4 h |
| Ex. 2 | Tb | 158 | 134 | 1 | 0.125 + 0.125 | 10% | Same as Ex. 1 |
| Ex. 3 | Tb | 158 | 134 | 1 | 125 + 0.125 | 10% | Same as Ex. 1 |
| Ex. 4 | Tb | 158 | 134 | 1 | 0.05 + 0.1 + 0.1 | 10% | Same as Ex. 1 |
| Ex. 5 | Tb | 158 | 134 | 1 | 125 + 0.125 | 10% | Same as Ex. 1 |
| Ex. 6 | Dy | 158 | 134 | 1 | 0.13 | 5% | Same as Ex. 1 |
| Ex. 7 | Gd | 158 | 134 | 1 | 0.125 + 0.125 | 10% | Same as Ex. 1 |
| Ex. 8 | Y | 158 | 134 | 1 | 0.05 + 0.1 + 0.1 | 10% | Same as Ex. 1 |
| Ex. 9 | Sc | 108 | 90 | 1 | 0.05 + 0.08 | 5% | Same as Ex. 1 |
| Ex. 10 | Yb | 108 | 90 | 1 | 0.1 + 0.06 | 6% | Same as Ex. 1 |
| Ex. 11 | La | 108 | 90 | 1 | 0.1 + 0.05 + 0.06 | 8% | Same as Ex. 1 |
| Ex. 12 | Ho | 108 | 90 | 1 | 0.05 + 0.1 + 0.1 | 10% | Same as Ex. 1 |
| Ex. 13 | Er | 108 | 90 | 1 | 0.08 + 0.1 + 0.07 | 10% | Same as Ex. 1 |
| Ex. 14 | Sm | 108 | 90 | 1 | 0.15 + 0.1 | 10% | Same as Ex. 1 |
| Comp. Ex. 1 | Tb | 158 | 134 | 1 | 0 | 0 | / |
| Comp. Ex. 2 | Tb | 158 | 134 | 1 | 0 | 0 | / |
| Comp. Ex. 3 | Tb | 158 | 134 | 1 | 0.03 + 0.03 + | 10% | Same as Ex. 1 |
| | | | | | 0.02 + 0.02 + 0.15 | | |
| Comp. Ex. 4 | Tb | 158 | 134 | 1 | 0.25 | 10% | Same as Ex. 1 |
| Comp. Ex. 5 | Tb | 158 | 134 | 1 | 125 + 0.125 | 10% | 1) 140° C.-0.5 h; |
| | | | | | | | 2) 157° C.-3 h; |
| | | | | | | | 3) 200° C.-4 h; |
| | | | | | | | 4) 300° C.-5 h; |
| | | | | | | | 5) 400° C.-10 h; |
| | | | | | | | 6) 500° C.-10 h; |
| | | | | | | | 7) 630° C.-17.5 h; |
| Comp. Ex. 6 | Tb | 158 | 134 | 1 | 0.125 + 0.125 | 10% | 630° C.-17.5 h |
| Comp. Ex. 7 | Tb | 158 | 134 | 1 | 0.13 | 5% | 1) 140° C.-0.5 h; |
| | | | | | | | 2) 157° C.-1.5 h; |
| | | | | | | | 3) 200° C.-1.5 h; |
| | | | | | | | 4) 250° C.-1.5 h; |
| | | | | | | | 5) 300° C.-2 h; |
| | | | | | | | 6) 350° C.-3 h; |
| | | | | | | | 7) 400° C.-3 h; |
| | | | | | | | 8) 450° C.-3 h; |
| | | | | | | | 9) 480° C.-3 h |
| Comp. Ex. 8 | Tb | 158 | 134 | 1 | 0.05 | 2% | 1) 140° C.-0.5 h; |
| | | | | | | | 2) 157° C.-3 h; |
| | | | | | | | 3) 200° C.-4 h; |
| | | | | | | | 4) 300° C.-5 h; |
| | | | | | | | 5) 330° C.-10 h; |
| Comp. Ex. 9 | Tb | 158 | 134 | 1 | 0.07 + 0.1 + | 15% | 1) 140° C.-0.5 h; |
| | | | | | 0.15 + 0.15 | | 2) 157° C.-1.5 h; |
| | | | | | | | 3) 200° C.-1.5 h; |
| | | | | | | | 4) 250° C.-1.5 h; |
| | | | | | | | 5) 300° C.-2 h; |
| | | | | | | | 6) 350° C.-3 h; |
| | | | | | | | 7) 400° C.-3 h; |
| | | | | | | | 8) 450° C.-3 h; |
| | | | | | | | 9) 500° C.-3 h; |
| | | | | | | | 10) 550° C.-4 h; |
| | | | | | | | 11) 600° C.-4 h; |
| | | | | | | | 12) 630° C.-4 h; |
| Comp. Ex. 10 | Tb | 158 | 134 | 1 | 0 | 10% | / |

TABLE 2
Table (2) of performance parameters of each example and comparative example

| | Solder | Welding | | | Rare Earth | Welding | |
|---|---|---|---|---|---|---|---|
| | melting | temper- | Power | Target | Content in | com- | |
| | point/ | ature/ | density/ | utilization | Welding | position | |
| No. | ° C. | ° C. | W/cm² | rate | Layer/ppm | segregation | Comment |
| Ex. 1 | 600 | 220 | 5 | 90% | <10 | ±0.1% | Non-welding-off |
| Ex. 2 | 600 | 220 | 8 | 90% | <10 | ±0.1% | Non-welding-off |
| Ex. 3 | 600 | 220 | 10 | 90% | <10 | ±0.1% | Non-welding-off |
| Ex. 4 | 600 | 220 | 10 | 90% | <10 | ±0.1% | Non-welding-off |
| Ex. 5 | 600 | 220 | 12 | 90% | <10 | ±0.1% | Non-welding-off |
| Ex. 6 | 600 | 220 | 7 | 90% | <10 | ±0.1% | Non-welding-off |
| Ex. 7 | 600 | 220 | 10 | 90% | <10 | ±0.1% | Non-welding-off |
| Ex. 8 | 600 | 220 | 12 | 90% | <10 | ±0.1% | Non-welding-off |
| Ex. 9 | 600 | 210 | 6 | 90% | <10 | ±0.1% | Non-welding-off |
| Ex. 10 | 600 | 220 | 7 | 90% | <10 | ±0.1% | Non-welding-off |
| Ex. 11 | 600 | 200 | 8 | 90% | <10 | ±0.1% | Non-welding-off |
| Ex. 12 | 600 | 220 | 9 | 90% | <10 | ±0.1% | Non-welding-off |
| Ex. 13 | 600 | 210 | 10 | 90% | <10 | ±0.1% | Non-welding-off |
| Ex. 14 | 600 | 190 | 12 | 90% | <10 | ±0.1% | Non-welding-off |
| Comp. | 156.6 | 220 | 5 | 82% | <10 | / | Non-welding-off |
| Ex. 1 | | | | | | | |
| Comp. | 156.6 | 220 | 6 | 15% | <10 | / | Welding-off |
| Ex. 2 | | | | | | | |
| Comp. | 600 | 220 | 10 | 88% | 8000 | ±0.1% | Non-welding-off |
| Ex. 3 | | | | | | | |
| Comp. | 550 | 220 | 9 | 85% | <10 | ±0.1% | Non-welding-off |
| Ex. 4 | | | | | | | |
| Comp. | 500 | 220 | 12 | 80% | <10 | ±1% | Non-welding-off |
| Ex. 5 | | | | | | | |
| Comp. | >550 | 220 | 5 | 30% | 35000 | ±1% | Welding-off |
| Ex. 6 | | | | | | | |
| Comp. | 200-500 | 220 | 7 | 10% | <10 | ±0.1% | Welding-off |
| Ex. 7 | | | | | | | |
| Comp. | 300 | 220 | 12 | 8% | <10 | ±0.1% | Welding-off |
| Ex. 8 | | | | | | | |
| Comp. | >600 | 220 | 6 | 60% | 15000 | 2% | Welding-off at |
| Ex. 9 | | | | | | | later stage |
| Comp. | 600 | 650 | 5 | 40% | >40000 | ±0.1% | Welding-off at |
| Ex. 10 | | | | | | | later stage |

It can be seen from the above-mentioned tables 1 and 2 that the rare earth rotary target and the preparation method therefor provided in the technical solution of the examples of the present application can improve the power of the sputtering target and improve the utilization rate of the target by adding an aluminum sheet in the low-temperature welding process in combination with the thermal treatment process.

Firstly, compared with pure indium welding, the utilization rate of the target increased from 82% to more than 89% by adding an aluminum sheet (aluminum content 3-10%) into the welding layer.

Secondly, compared with pure indium welding, the addition of aluminum sheet in the welding layer can significantly increase the melting point of the solder, and the melting point increases to more than 400° C., which is beneficial to increase the power of the sputtering target, and ensure that the target was not welded off, i.e. the solder does not melt, the back tube and the target tube do not slip, and the target power increases from 5 W/cm² to 6-12 W/cm².

Thirdly, a reasonable thermal treatment process can shorten the total thermal treatment time, make the melting point of solder close to the theoretical melting point, and reduce the contamination of solder on the target, prevent the welding-off of the solder at a later stage. In addition, it overcomes the problem that the one-step heating thermal treatment process may lead to the melting of solder, the contamination of the target, and the high target composition in the solder layer.

Fourthly, the thickness of an individual aluminum sheet is controlled within 0.05-0.15 mm, which is beneficial to improve the utilization rate of the target, increase the sputtering power density, and reduce the contamination of the target by the welding layer. If an individual aluminum sheet has an excessive thickness, it will make it difficult to control the melting point of the solder. At this time, multiple aluminum sheets can be combined to achieve better control of the melting point of the solder.

Lastly, compared with the conventional indium soldering temperature of 220° C., if 600° C. solder is used, the soldering temperature needs to exceed 600° C., while the examples provided by the present application can realize welding at 220° C. The melting point of solder can be increased to 600° C. by the treatment, reducing the welding difficulty, reducing the contamination of the target by solder, and increasing the sputtering power density of the target.

In summary, the examples of the present application relate to a rare earth rotary target and a preparation method therefor, which is suitable for a rare earth metal and alloy target used in magnetic material coating, grain boundary diffusion, storage, and electronic information. The rare earth rotary target includes a back tube and at least one rare earth target tube welded outside of the back tube; the back tube and the rare earth target tube are welded by means of an intermediate welding layer, wherein the intermediate welding layer comprises a metal indium solder and at least a one aluminum sheet arranged in the metal indium solder, the aluminum content in the intermediate welding layer is 3-10 wt. %, and the back tube, the aluminum sheet and the rare earth target tube are concentric cylindrical structures. According to the technical solution of the examples of the present application, starting from the aspects of target welding, solder alloying, etc. by adding an aluminum sheet in the middle of the solder layer and combining with the thermal treatment process, the melting point of the solder can be increased, which is increased from 156.6° C. to higher than 400° C., which can significantly increase the power density of the sputtering target, thus achieving the purpose of improving the sputtering power density and a target utilization rate of rare earth rotary targets, realizing low-temperature welding, and slowing down oxidation of rare earth targets.

It is to be understood that the above-described specific implementations of the present application are merely illustrative or explanatory of the principles of the present application and are not restrictive of the present application. Therefore, any modifications, equivalent replacements, improvements, etc. made without deviating from the spirit and scope of the present application shall be included within the scope of the present application. Furthermore, it is intended that the appended claims cover all such variations and modifications that fall within the scope and boundaries of the appended claims of the present application, or equivalent forms of such scope and boundaries.

What is claimed is:

1. A rare earth rotary target, comprising a back tube and at least one rare earth target tube welded outside of the back tube;
wherein the back tube and the rare earth target tube are welded via an intermediate welding layer; the intermediate welding layer comprises a metal indium solder and an aluminum sheet arranged in the metal indium solder; the aluminum content in the intermediate welding layer is 3-10 wt. %; and the back tube, the aluminum sheet, and the rare earth target tube are concentric cylindrical structures.

2. The rare earth rotary target according to claim 1, wherein the rare earth target tube comprises any one of the rotary target tubes of lanthanum, cerium, praseodymium, neodymium, samarium, europium, gadolinium, terbium, dysprosium, holmium, erbium, thulium, ytterbium, lutetium, yttrium, and scandium.

3. The rare earth rotary target according to claim 1, wherein an individual aluminum sheet has a thickness of 0.05-0.15 mm.

4. A preparation method for the rare earth rotary target according to claim 1, comprising the following steps:
filling a metal indium solder between the back tube and the rare earth target tube at a preset welding temperature, and placing the aluminum sheet in the metal indium solder; or placing the aluminum sheet in the metal indium solder in advance, filling the metal indium solder with the placed aluminum sheet between the back tube and the rare earth target tube, and welding the back tube and the rare earth target tube to obtain a welded rare earth rotary target;
subjecting the welded rare earth rotary target to a thermal treatment; and
cooling the thermal-treated rare earth rotary target to room temperature and cleaning the same.

5. The preparation method according to claim 4, further comprising:
pre-coating the aluminum sheet with a layer of metal indium solder prior to filling.

6. The preparation method according to claim 4, wherein the preset welding temperature is 190-230° C.

7. The preparation method according to claim 4, wherein the thermal treatment comprises the following steps:
cooling the welded rare earth rotary target to room temperature and then cleaning the same;
placing the cleaned rare earth rotary target in a vacuum thermal treatment furnace, and vacuum pumping to less than 10⁻³ Pa; and
performing a direct thermal treatment on the rare earth rotary target or performing a thermal treatment after charging an inert gas, wherein the thermal treatment temperature is 140° C.-640° C., and the thermal treatment time is 0.5-50 h.

8. The preparation method according to claim 7, wherein the thermal treatment is a step-wised insulation treatment, comprising:
a thermal treatment at 140° C. for 0.5-1 h;
a thermal treatment at 157° C. for 1-3 h;
a thermal treatment at 200° C. for 1-3 h;
a thermal treatment at 250° C. for 1-3 h;
a thermal treatment at 300° C. for 1-3 h;
a thermal treatment at 350° C. for 1-5 h;
a thermal treatment at 400° C. for 1-5 h;
a thermal treatment at 450° C. for 1-5 h;
a thermal treatment at 500° C. for 1-5 h;
a thermal treatment at 550° C. for 1-5 h;
a thermal treatment at 600° C. for 1-5 h; and
a thermal treatment at 630° C. for 1-6 h.
